(19) United States
(12) Patent Application Publication
(10) Pub. No.: US 2024/0075534 A1
(43) Pub. Date: Mar. 7, 2024

(54) COATED CUTTING TOOL

(71) Applicant: YG-1 Co., Ltd, Incheon (KR)

(72) Inventors: SOO HYUN CHA, Chungju-si (KR); GEUN WOO PARK, Chungju-si (KR); SANG YOUNG JO, Chungju-si (KR); TAE YANG HAN, Chungju-si (KR)

(21) Appl. No.: 18/450,225

(22) Filed: Aug. 15, 2023

(30) Foreign Application Priority Data
Aug. 24, 2022 (KR) 10-2022-0106210

(51) Int. Cl. B23B 27/14; C23C 28/04

(52) U.S. Cl. CPC B23B 27/148; C23C 28/042; C23C 28/044; B23B 2224/24

(57) ABSTRACT

A coated cutting tool having excellent wear resistance and controlled brittleness is provided. An embodiment of the present disclosure provides a coated cutting tool including: a substrate; and a cutting layer disposed on the substrate, wherein: the cutting layer includes a brittleness suppressing layer and a wear-resistant layer disposed on the brittleness suppressing layer; the substrate includes a hard alloy body such as cemented carbide, cermet, ceramic, cubic boron nitride-based materials, or high-speed steel; the brittleness suppressing layer includes a first layer and a second layer disposed on the first layer; the first layer and the second layer each independently includes any one of (Al_{b}Ti_{1-b})X (where 0.6<b<0.8, and X is at least one selected from N, C, CN, NO, CO, and CNO) and (Ti_{c}Al_{1-c})X (where 0.4<c≤0.5, and X is at least one selected from N, C, CN, NO, CO, and CNO); and the first layer and the second layer include materials different from each other.

### CROSS-REFERENCE TO RELATED APPLICATION

This application claims priority to Korean Patent Application No. 10-2022-0106210, filed on Aug. 24, 2022 and all the benefits accruing therefrom under 35 U.S.C. § 119, the contents of which are incorporated by reference in their entirety.

### BACKGROUND

The present disclosure relates to a coated cutting tool.

Generally, a coated cutting tool has a hard phase of WC and cubic carbonitride and includes a tough substrate and a coating. The elemental composition contained in the coating disposed on a surface of the substrate is prepared differently from a bulk composition, and may exhibit good wear resistance and strength at the same time. As a result, the life of the cutting tool is extendable for different machining conditions.

As various cutting materials have been developed along with industrial development, there are increasing demands for performance and life improvement of cutting tools for machining the cutting materials. As part of a response to meet these demands, tool coating technology is being constantly developed, and performance improvement is being attempted in various ways from coating deposition schemes to deposition compositions and structures.

A coated cutting tool which was developed in the early stage of industrial development employed a coating with a simple structure. However, nitride-based ceramic coatings are used in various ways in most tools currently, and carbide or oxide-based ceramic coatings are being utilized for some special-purpose machining. Meanwhile, TiAlN, which is a typical nitride-based coating, is able to secure oxidation resistance and wear resistance at the same time as the characteristics of aluminum (Al) are added to high hardness. Thus, since the 1990s, TiAlN has been widely used as a coating material for cemented carbide and various metal tools.

Nevertheless, with the introduction of new cutting materials such as aerospace materials, schemes such as high-speed dry machining that exclude the use of coolant have spread to improve machining efficiency, and in terms of this high-hardness and high-temperature machining, a TiAlN coating showed limitations such as lack of welding resistance and wear resistance, and decrease in hardness of the coating. For example, alloys such as heated steel and high-hardness steel have low thermal conductivity and high reactivity with tools to cause high temperatures during machining, and this conduction of heat accelerates wear of a coating and lowers hardness of the coating.

In addition, if only the hardness of a coating is increased, another limitation may arise in that, even if the life of the coating is not exhausted, the coating becomes unusable due to the brittleness of the coating with high hardness. Therefore, research on a coating having high wear resistance and hardness and controlled brittleness has been continuously conducted.

### SUMMARY

The present disclosure provides a coated cutting tool having excellent wear resistance and heat resistance and controlled brittleness.

The present disclosure also provides a coated cutting tool of which the life is extendable by increasing adhesion between layers that constitute a coating and which secures the stability of a product as damage to a workpiece caused by tool breakage is reduced.

The present disclosure also provides a method for producing the coated cutting tool.

Aspects of the present disclosure are not limited to the above-described aspects, and other aspects and advantages of the present disclosure which are not described above can be understood by the following descriptions and will be more clearly understood by embodiments of the present disclosure. Further, it will be readily apparent that the aspects and advantages of the present disclosure may be achieved by means of the instrumentalities indicated in the claims, and combinations thereof.

In accordance with an exemplary embodiment of the present invention, a coated cutting tool includes: a substrate; and a cutting layer disposed on the substrate, wherein: the cutting layer includes a brittleness suppressing layer and a wear-resistant layer disposed on the brittleness suppressing layer; the substrate includes a hard alloy body such as cemented carbide, cermet, ceramic, cubic boron nitride-based materials, or high-speed steel; the brittleness suppressing layer includes a first layer and a second layer disposed on the first layer; the first layer and the second layer each independently includes any one of (Al_{b}Ti_{1-b})X (where 0.6<b<0.8, and X is at least one selected from N, C, CN, NO, CO, and CNO) and (Ti_{c}Al_{1-c})X (where 0.4<c≤0.5, and X is at least one selected from N, C, CN, NO, CO, and CNO); and the first layer and the second layer include materials different from each other.

The first layer may include (Ti_{c}Al_{1-c})X (where 0.4<c≤0.5, and X is at least one selected from N, C, CN, NO, CO, and CNO) and the second layer may include (Al_{b}Ti_{1-b})X (where 0.6<b<0.8, and X is at least one selected from N, C, CN, NO, CO, and CNO).

The brittleness suppressing layer may include a first alternating layer in which the first and second layers are alternately laminated with each other. Specifically, the first alternating layer may include two or more multilayers, and the thicknesses of the first and second layers constituting the multilayers may each independently exceed 50 nm. In addition, a thickness ratio of the second layer and the first layer (second layer: first layer) may be 1:1.5 to 1:5.

The wear-resistant layer according to the present disclosure may include (Ti₁₋ₐSiₐ)X (where 0.1<a<0.3, and X is at least one selected from N, C, CN, NO, CO, and CNO).

The cutting layer may further include a second alternating layer disposed between the brittleness suppressing layer and the wear-resistant layer. Specifically, the second alternating layer may include at least one structure in which a first wear-resistant layer, the second layer, and the first layer are sequentially laminated, and the first wear-resistant layer may include (Ti₁₋ₐSiₐ)X (where 0.1<a<0.3, and X is at least one selected from N, C, CN, NO, CO, and CNO).

The cutting layer may further include an intervening layer disposed on the second alternating layer. Specifically, the intervening layer may include a lower layer disposed directly below the wear-resistant layer, and the lower layer may include (Al_{b}Ti_{1-b})X (where 0.6<b<0.8, and X is at least one selected from N, C, CN, NO, CO, and CNO).

The solution to the above limitations does not enumerate all the features of the present disclosure. Various features of the present disclosure and its advantages and effects will be understood in more detail with reference to the following specific embodiments.

### BRIEF DESCRIPTION OF THE DRAWINGS

Exemplary embodiments can be understood in more detail from the following description taken in conjunction with the accompanying drawings, in which:

FIG. 1 is a schematic diagram of a coated cutting tool according to an embodiment of the present disclosure;

FIG. 2 is a schematic diagram of a coated cutting tool according to another embodiment of the present disclosure;

FIG. 3 is a schematic diagram of a coated cutting tool according to another embodiment of the present disclosure;

FIG. 4 is a flow chart showing a method for producing a coated cutting tool according to an embodiment of the present disclosure;

FIG. 5 is an X-ray diffraction analysis result of a cutting layer included in a coated cutting tool formed by a method according to Embodiments and Comparative Examples; and

FIG. 6 is a scanning electron microscope (SEM) picture of a cutting layer according to Embodiment 1.

### DETAILED DESCRIPTION OF EMBODIMENTS

Hereinafter, each configuration of the present disclosure will be described in more detail so that those skilled in the art can easily practice it, but this is only one example, and the scope of the present disclose is not limited.

An embodiment of the present disclosure provides a coated cutting tool including: a substrate; and a cutting layer disposed on the substrate, wherein: the cutting layer includes a brittleness suppressing layer and a wear-resistant layer disposed on the brittleness suppressing layer; the substrate includes a hard alloy body such as cemented carbide, cermet, ceramic, cubic boron nitride-based materials, or high-speed steel; the brittleness suppressing layer includes a first layer and a second layer disposed on the first layer; the first layer and the second layer each independently includes any one of (Al_{b}Ti_{1-b})X (0.6<b<0.8, X is at least one selected from N, C, CN, NO, CO, and CNO) and (Ti_{c}Al_{1-c})X (0.4<c≤0.5, X is at least one selected from N, C, CN, NO, CO, and CNO); and the first layer and the second layer include materials different from each other.

With the introduction of new cutting materials such as aerospace materials, high-speed dry machining schemes that exclude the use of coolant have spread to improve machining efficiency. In this high-hardness and high-temperature machining scheme, there were limitations in that a coating deposited on a substrate had significantly lowered welding resistance and wear resistance and the hardness of the coating was lowered. At this time, if only the hardness of the coating was increased, there was a limitation in that, even if the life of the coating is not exhausted, the coating becomes unusable due to the brittleness of the coating having high hardness. According to an embodiment of the present disclosure, a coated cutting tool having high wear resistance and controlled brittleness via a combination of a brittleness suppressing layer and a wear-resistant layer may be provided. In addition, according to another embodiment of the present disclosure, a coated cutting tool of which the life is extendable by increasing adhesion between layers that constitute a coating and which secures the stability of a product as damage to a workpiece caused by tool breakage is reduced may be provided.

Hereinafter, the configuration of the present disclosure will be described in more detail with reference to the drawings.

1. Coated Cutting Tool

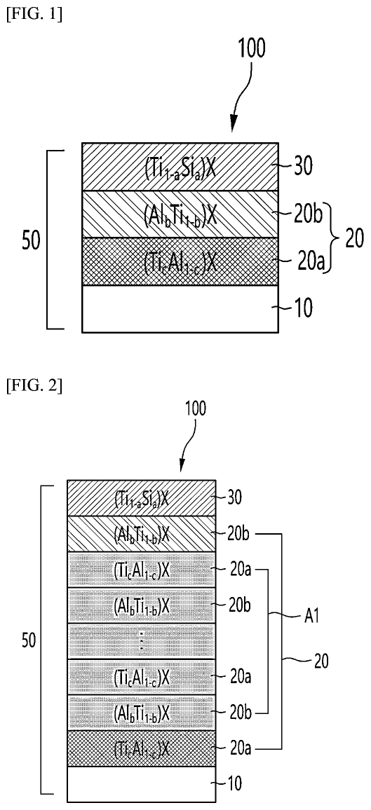

FIG. 1 is a coated cutting tool according to an embodiment of the present disclosure.

Referring to FIG. 1, a coated cutting tool 100 according to an embodiment of the present disclosure includes a substrate 10 and a cutting layer 50.

The substrate 10 according to the present disclosure may include a hard alloy body of cemented carbide, cermet, ceramic, cubic boron nitride-based materials, or high-speed steel. The substrate may include, for example, cemented carbide (90 wt % WC+10 wt % Co).

The cutting layer 50 according to the present disclosure may be disposed on the substrate 10 and may be specifically disposed directly on the substrate 10. The cutting layer 50 may be deposited on a surface of the substrate 10 to improve wear resistance and effectively control brittleness.

The cutting layer 50 according to the present disclosure may include a brittleness suppressing layer 20 and a wear-resistant layer 30 disposed on the brittleness suppressing layer 20. Specifically, the wear-resistant layer 30 may be disposed directly on the brittleness suppressing layer 20. That is, the brittleness suppressing layer 20 may be disposed between the substrate 10 and the wear-resistant layer 30.

The brittleness suppressing layer 20 according to the present disclosure may include a first layer 20a and a second layer 20b disposed on the first layer 20a. Specifically, the brittleness suppressing layer 20 may perform a function of suppressing brittleness of a wear-resistant layer with high hardness.

According to an embodiment of the present disclosure, the first layer 20a and the second layer 20b may each independently include any one of (Al_{b}Ti_{1-b})X (0.6<b<0.8, X is at least one selected from N, C, CN, NO, CO, and CNO) and (Ti_{c}Al_{1-c})X (0.4<c≤0.5, X is at least one selected from N, C, CN, NO, CO, and CNO), and the first layer 20a and the second layer 20b may include materials different from each other. Specifically, the first layer may include (Ti_{c}Al_{1-c})X (0.4<c≤0.5, X is at least one selected from N, C, CN, NO, CO, and CNO) and the second layer may include (Al_{b}Ti_{1-b})X (0.6<b<0.8, X is at least one selected from N, C, CN, NO, CO, and CNO). When the first and second layers include Ti, Al, and X and b and c satisfy the above numerical ranges, a certain level of wear resistance may be achieved and at the same time the brittleness of a wear-resistant layer having high hardness may be more effectively suppressed.

According to an embodiment of the present disclosure, the first layer 20a and the second layer 20b may each independently have a thickness of 0.1 μm to 5.0 μm, specifically 0.5 μm to 3.0 μm, and more specifically 0.5 μm to 2.0 μm. When the thicknesses of the first and second layers satisfy the above numerical range, a certain level of wear resistance may be achieved and at the same time the brittleness of a wear-resistant layer with high hardness may be more effectively suppressed.

The wear-resistant layer 30 according to the present disclosure may be disposed on the brittleness suppressing layer 20, and may be specifically disposed directly on the brittleness suppressing layer 20. The wear-resistant layer 30 may impart oxidation resistance and wear resistance to the cutting layer.

Specifically, the wear-resistant layer 30 may include (Ti₁₋ₐSiₐ)X (0.1<a<0.3, X is at least one selected from N, C, CN, NO, CO, and CNO). When the wear-resistant layer includes silicone, coating deterioration at a high temperature, which occurs during machining, is suppressed, and the life of the coated cutting tool may be increased. In addition, as the wear-resistant layer contains silicone to form a two-phase structure composed in an NaCl type (face-centered cubic lattice structure (fcc structure)) combined with amorphous Si₃N₄ or SiNx, properties suitable for machining of a high hardness workpiece may be provided.

Specifically, on the basis of 100 atomic % (100 at %) of the sum of Ti content and Si content, the Si content may be greater than 10 at % and less than or equal to 25 at %, and more specifically, may be 15 at % to 25 at %. When the Si content satisfies the above numerical range, an excellent balance may be achieved for machinability and brittleness of a coating, and an amorphous phase is appropriately maintained, and thus a limitation of excessive decrease in hardness may be effectively prevented.

The wear-resistant layer 30 according to the present disclosure may have a thickness of 0.5 μm to 10.0 μm, specifically 0.5 μm to 5.0 μm, and more specifically 1.0 μm to 3.0 μm. When the thickness of the wear-resistant layer 30 satisfies the above numerical range, a wear resistance function may be sufficiently achieved, and at the same time the brittleness of a coating may be controlled to an appropriate level, and a welding and peeling phenomenon caused by the compressive stress of an amorphous film may be effectively prevented.

FIG. 2 is a coated cutting tool according to another embodiment of the present disclosure. The above-described parts and repeated descriptions will be briefly described or omitted.

Referring to FIG. 2, the brittleness suppressing layer 20 according to an embodiment of the present disclosure may include a first alternating layer A1 in which the first and second layers 20a and 20b are alternately laminated. When the hardness of the wear-resistant layer 30 is higher than a certain level, the first alternating layer A1 may effectively prevent a limitation in that each layer is not firmly connected and prematurely separated due to a difference in lattice constants between coatings. Through the first alternating layer A1, a difference in lattice constants, a difference in elastic moduli, and a stacking cycle may be effectively controlled, and accordingly, brittleness that may occur in the wear-resistant layer may be suppressed. In addition, through the first alternating layer A1, cracks may be effectively prevented from occurring in a coating, and thus the life of the tool is extendable.

According to another embodiment of the present disclosure, a thickness ratio of the second layer 20b and the first layer 20a (second layer: first layer) may be 1:1.5 to 1:5, specifically 1:1.5 to 1:3. When the thickness ratio of the second layer and the first layer satisfies the above numerical range, a certain level of wear resistance may be achieved and at the same time the brittleness of a wear-resistant layer having high hardness may be more effectively suppressed. In this case, the total thickness of the cutting layer 50 may be 0.1 μm to 20 μm, specifically 0.1 μm to 5.0 μm.

According to another embodiment of the present disclosure, the first alternating layer A1 may include two or more multilayers, and the thicknesses of the first and second layers 20a and 20b constituting the multilayers may each independently exceed 50 nm. Specifically, the thicknesses of the first and second layers 20a and 20b each may be independently greater than 50 nm and less than or equal to 300 nm. When the thicknesses of the first and second layers satisfy the above numerical range, adhesion between layers may be sufficiently maintained and spontaneous peeling may be effectively prevented.

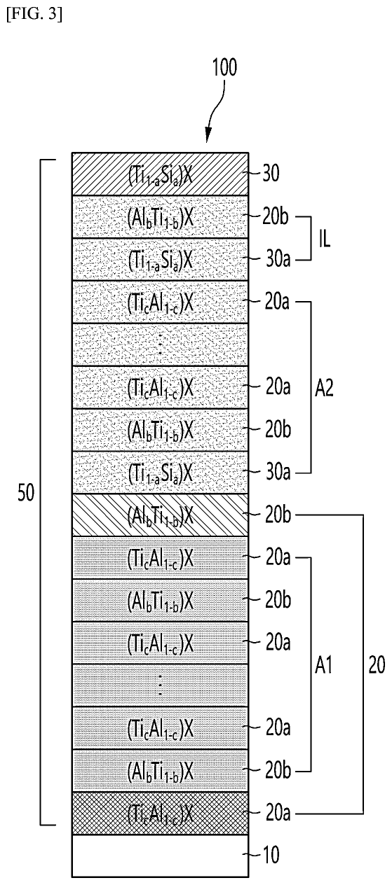

FIG. 3 is a coated cutting tool according to another embodiment of the present disclosure. The above-described parts and repeated descriptions will be briefly described or omitted.

Referring to FIG. 3, a cutting layer 50 according to another embodiment of the present disclosure may further include a second alternating layer A2 disposed between the brittleness suppressing layer 20 and the wear-resistant layer 30.

Specifically, the second alternating layer A2 may include at least one structure in which a first wear-resistant layer 30a, the second layer 20b, and the first layer 20a are sequentially laminated, and the first wear-resistant layer includes (Ti₁₋ₐSiₐ)X (0.1<a<0.3, X is at least one selected from N, C, CN, NO, CO, and CNO). More specifically, the second alternating layer A2 may be a laminated structure with repetition of 2 times to 50 times, specifically 5 to 10 times, of structures, each of which has the first wear-resistant layer 30a, the second layer 20b, and the first layer 20a that are sequentially laminated and is used as a repeating unit (a first wear-resistant layer +a second layer+a first layer). The adhesion of a coating may be improved through the second alternating layer A2, and thus the life of the tool is extendable, and an additional brittle suppression effect may also be achieved. In this case, the total thickness of the cutting layer 50 may be 0.1 μm to 20 μm, specifically 0.1 μm to 5 μm.

According to another embodiment of the present disclosure, the thicknesses of the first, second, and first wear-resistant layers 20a, 20b, and 30a constituting the second alternating layer A2 may each independently exceed 50 nm. Specifically, the thicknesses of the first, second, and first wear-resistant layers 20a, 20b, and 30a each may be independently greater than 50 nm and less than or equal to 300 nm. When the thicknesses of the first and second layers and the thickness of the first wear-resistant layer satisfy the above numerical range, adhesion between layers may be sufficiently maintained and spontaneous peeling may be effectively prevented.

According to another embodiment of the present disclosure, the cutting layer 50 may further include an intervening layer IL disposed on the second alternating layer A2. Specifically, the intervening layer IL may include a lower layer disposed directly below the wear-resistant layer 30, and the lower layer may include (Al_{b}Ti_{1-b})X (0.6<b<0.8, X is at least one selected from N, C, CN, NO, CO, and CNO). As the lower layer including (Al_{b}Ti_{1-b})X is disposed directly below the wear-resistant layer, a coated cutting tool having high wear resistance and controlled brittleness may be provided.

According to another embodiment of the present disclosure, the cutting layer 50 may first grow in a [200] direction, and may show a (200) peak and a (111) peak in X-ray diffraction analysis. In the X-ray diffraction analysis, a ratio of the (200) peak to the (111) peak may be 3 or more or may be 3 to 10.

The cutting layer 50 according to an embodiment of the present disclosure may have a hardness of, for example, 35 GPa to 55 GPa or 40 GPa to 55 GPa. The hardness may be measured by a nanoindentation scheme using, for example, a nanoindentor NHT3.

According to another embodiment of the present disclosure, the cutting layer 50 may include a phase mixture of cubic phase and hexagonal phase. Specifically, the cutting layer 50 may have a columnar crystal and polycrystalline alternating layered structure, and may be analyzed by scanning electron micrograph.

2. Method for Producing a Coated Cutting Tool

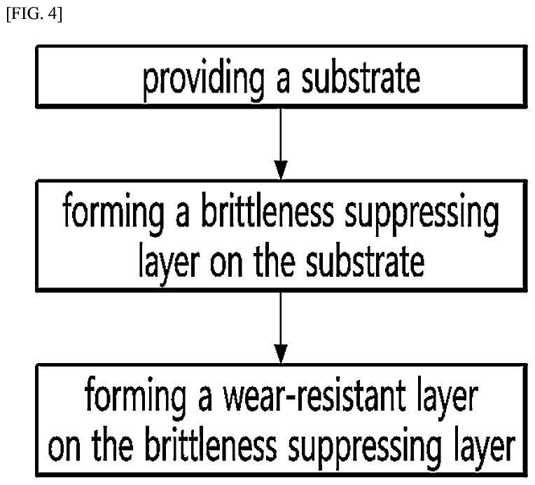

FIG. 4 is a flow chart showing a method for producing a coated cutting tool according to an embodiment of the present disclosure. The above-described parts and repeated descriptions will be briefly described or omitted.

Another embodiment of the present disclosure may provide a method for producing the coated cutting tool.

A method for producing the coated cutting tool according to the present disclosure may include: a process (Si) of providing a substrate; a process (S2) of forming a brittleness suppressing layer on the substrate; and a process (S3) of forming a wear-resistant layer on the brittleness suppressing layer.

Specifically, at least one of the process (S2) or the process (S3) may be a process performed using a physical vapor deposition scheme. Specifically, at least one of the process (S2) or the process (S3) may be a process performed using a cathodic arc deposition scheme.

For example, at least one of the process (S2) or the process (S3) may be a process performed using a gas pressure of 0.5 Pa to 5.0 Pa, a bias of −50 V to −300 V, a temperature of 350° C. to 700° C., and a current of 50 A to 200 A in an inert gas atmosphere.

Hereinafter, embodiments of the present disclosure will be described in detail so that those skilled in the art can easily carry out the present disclosure, but this is only one example, and the scope of the present disclosure is not limited by the following descriptions.

### Production Example: Production of a Coated Cutting Tool

A coated cutting tool was produced with a composition according to Table 1 below.

### Embodiments 1 to 4: Coated Cutting Tool Having First and Second Alternating Layers

In order to remove foreign matters from the surface of a cemented carbide (90 wt % WC+10 wt % Co) substrate and improve the adhesion of a coating, dry and wet blasting was performed to make the surface smooth. Thereafter, a cutting layer including a brittleness suppressing layer and a wear-resistant layer was formed on the cemented carbide substrate by using an arc ion plating scheme, which is one of physical vapor deposition (PVD) schemes. The model number of a coated cutting tool is ENMX0604-TR. Specifically, the cemented carbide substrate was introduced into a chamber, and ion bombardment processing was performed in an argon gas atmosphere to further clean the surface of the substrate. Then, a cutting layer was formed using an arc target made of TiAl, AlTi, TiSi, and the like, and an arc ion plating scheme. In a process of forming the cutting layer, an initial vacuum pressure was 5.0×10⁻² Pa or less, a gas atmosphere was formed by injecting N₂ as a reaction gas, and a deposition temperature was set in the range of 450° C. to 600° C. When forming the cutting layer, an arc current of 100 A to 200 A was applied to a main target, and a DC-type bias voltage of −30 V to −150 V was applied to increase adhesion to the substrate. The average thickness of layers included in the multilayer cutting layer was controlled by changing a cathode arc current and a rotational speed (0.1 rpm to 5 rpm) of equipment, and finally a coated cutting tool was produced.

### Embodiment 5: Coated Cutting Tool Having Only a First Alternating Layer

A coated cutting tool was produced in the same manner as in Embodiments 1 to 4, but the forming of a second alternating layer was omitted.

### Embodiment 6: Coated Cutting Tool Having No First and Second Alternating Layers

A coated cutting tool was produced in the same manner as in Embodiments 1 to 4, but the forming of first and second alternating layers was omitted.

### Embodiments 7 and 8: Coated Cutting Tool in which a Thickness Ratio of First and Second Alternating Layers is Adjusted>

A coated cutting tool was produced in the same manner as in Embodiments 1 to 4, but a thickness ratio between a first layer and a second layer was changed when forming first and second alternating layers.

### Comparative Examples 1 and 2: Coated Cutting Tool Having No Brittleness Suppressing Layer and First and Second Alternating Layers

A coated cutting tool was produced in the same manner as in Embodiments 1 to 4, but the forming of a brittleness suppressing layer and first and second alternating layers was omitted.

TABLE 1

| | Respective | | Total | | Total | | | |
|---|---|---|---|---|---|---|---|---|
| | composition of | | brittleness | | wear- | | | |
| | brittleness | | suppressing | | resistant | Presence/absence | Presence/absence | |
| | suppressing layer¹⁾ | | layer | Wear- | layer | of first | of second | |
| | Second | First | Thickness | resistant | thickness | alternating | alternating | |
| Division | layer | layer | (μm) | layer | (μm) | layer²⁾ | layer³⁾ | Drawing |
| Embodiment | AlTiN | TiAlN | 2.7 | TiSiN | 1.4 | Present | Present | FIG. 3 |
| 1 | (67:33) | (50:50) | | (85:15) | | (n1 = 9) | (n2 = 9) | |
| Embodiment | AlTiN | TiAlN | 2.4 | TiSiN | 1.4 | Present | Present | FIG. 3 |
| 2 | (67:33) | (50:50) | | (70:30) | | (n1 = 8) | (n2 = 8) | |
| Embodiment | AlTiN | TiAlN | 2.4 | TiSiN | 0.3 | Present | Present | FIG. 3 |
| 3 | (67:33) | (50:50) | | (85:15) | | (n1 = 8) | (n2 = 8) | |
| Embodiment | AlTiN | TiAlN | 0.9 | TiSiN | 2.5 | Present | Present | FIG. 3 |
| 4 | (67:33) | (50:50) | | (85:15) | | (n1 = 3) | (n2 = 2) | |
| Embodiment | AlTiN | TiAlN | 1.5 | TiSiN | 1.4 | Present | Absent | FIG. 2 |
| 5 | (67:33) | (50:50) | | (85:15) | | (n1 = 5) | | |
| Embodiment | AlTiN | TiAlN | 2.8 | TiSiN | 1.8 | Absent | Absent | FIG. 1 |
| 6 | (67:33) | (50:50) | | (85:15) | | | | |
| Embodiment | AlTiN | TiAlN | 2.4 | TiSiN | 1.5 | Present | Present | FIG. 3 |
| 7 | (67:33) | (50:50) | | (85:15) | | (n1 = 4) | (n2 = 2) | |
| Embodiment | AlTiN | TiAlN | 2.5 | TiSiN | 1.5 | Present | Present | FIG. 3 |
| 8 | (67:33) | (50:50) | | (85:15) | | (n1 = 10) | (n2 = 6) | |
| Comparative | — | — | — | TiAlN | 3.3 | — | — | |
| Example 1 | | | | (50:50) | | | | |
| Comparative | — | — | — | TiAlSiN | 3.0 | — | — | |
| Example 2 | | | | (35:60:5) | | | | |

Unit: when the total of remaining components except nitrogen (N), which is a non-metallic component, is set as 100 atomic % (at %), the content of each composition in a brittleness suppressing layer and a wear-resistant layer means the atomic % (at %) of each of the remaining components except for nitrogen.
¹⁾Brittleness suppressing layer: with respect to a thickness ratio of a first layer to a second layer (second layer:first layer), Embodiments 1 to 6 are 1:2, Embodiment 7 is 1:5, and Embodiment 8 is 1:1.5.
²⁾First alternating layer: a structure with repetition of more than 2 and less than 50 times (n1) of repeating units, each of which has first and second layers (thickness = more than 200 nm and less than 5,000 nm).
³⁾Second alternating layer: a structure with repetition of more than 2 and less than 50 times (n2) of repeating units, each of which has a wear-resistant layer, a second layer, and a first layer that are sequentially laminated (thickness = more than 450 nm and less than 7,500 nm).

### Experimental Example 1: X-Ray Diffraction Analysis of a Cutting Layer

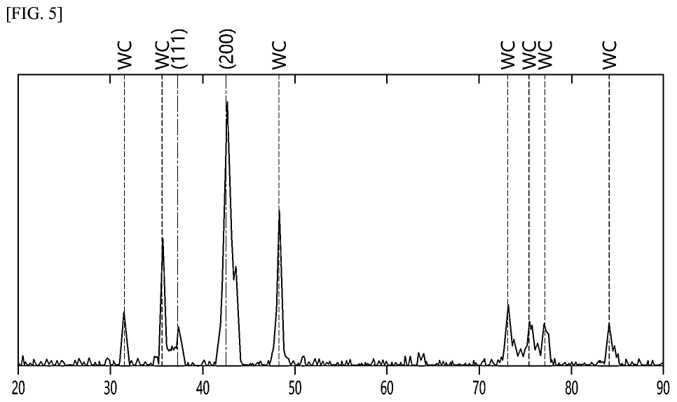

FIG. 5 is an X-ray diffraction analysis result of a cutting layer included in a coated cutting tool formed by a method according to Embodiments and Comparative Examples. X-ray diffraction of the cutting layer included in the coated cutting tool formed by the method according to Embodiments and Comparative examples was analyzed using an Empyrean X-ray diffractometer manufactured by Malvern Panalytical. Specifically, the X-ray diffraction measurement was performed using CuKα-radiation, at a point focus at 40 Kv and 40 Ma, and over a range of 20 degrees to 90 degrees with a step size of 0.065.

Referring to FIG. 5, a peak corresponding to tungsten carbide (WC) of a substrate, a (200) peak, and a (111) peak appeared. Since the peak intensity of a (200) plane of the cutting layer was the highest, it can be confirmed that the cutting layer first grows in a [200] direction. In addition, it can be confirmed that a ratio of the (200) peak to the (111) peak is 3 or more or in the range of 3 to 10.

### Experimental Example 2: Nanoindentation Hardness Measurement of a Cutting Layer

The hardness of the cutting layer included in the coated cutting tool formed by the method according to Embodiments was measured by a nanoindentation scheme using a nanoindentor NHT3 manufactured by Anton Paar.

TABLE 2

| | Nanoindentation hardness of cutting layer (GPa) |
|---|---|
| Embodiment 1 | 43.1 |
| Embodiment 2 | 38.5 |
| Embodiment 3 | 32.4 |
| Embodiment 4 | 41.6 |
| Embodiment 5 | 40.2 |
| Embodiment 6 | 35.7 |
| Embodiment 7 | 39.4 |
| Embodiment 8 | 44.5 |

Referring to Table 2, it can be confirmed that the hardness of the cutting layer formed by the method according to all Embodiments has a nanoindentation hardness in the range of 25 GPa to 50 GPa, and it can be confirmed that the desired level of wear resistance is sufficiently implemented.

### Experimental Example 3: Scanning Electron Microscopy Analysis of a Cutting Layer

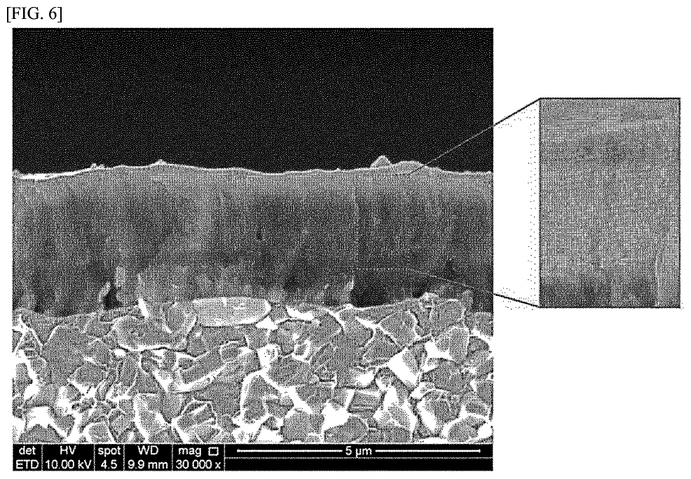

FIG. 6 is a scanning electron microscope (SEM) picture of a cutting layer according to Embodiment 1.

Referring to FIG. 6, it can be confirmed that the cutting layer according to Embodiment 1 has a columnar structure and has grown to include a phase mixture in which a cubic phase and a hexagonal phase are mixed. That is, it can be confirmed that the cutting layer according to an embodiment of the present disclosure has a columnar crystal structure and a polycrystalline alternating layered structure.

### Experimental Example 4: Life Measurement of a Coated Cutting Tool

The life of the coated cutting tool formed by the method according to Embodiments and Comparative Examples was measured under the conditions shown in Table 3 below, and the measurement results are shown in Table 4 below.

TABLE 3

| | |
|---|---|
| Primary test | Secondary test |
| measurement | measurement |
| conditions | conditions |

| | | |
|---|---|---|
| Shape | ENMX0604-TR | ENMX0604-TR |
| Applied field | MCT machining, | MCT machining, |
| | lamping machining | lamping machining |
| workpiece | NAK80 (HRc 42) | SKD61 (HRc 48) |

| | | | | |
|---|---|---|---|---|
| Cutting speed | 240 | m/min | 160 | m/min |
| Moving speed | 0.6 | mm/rev | 0.6 | mm/rev |
| Cutting depth (ap) | 0.7 | mm | 0.7 | mm |
| Cutting depth (ae) | 13 | mm | 13 | mm |

| | | |
|---|---|---|
| Cutting oil | Not used | Not used |
| Life determination | Vb > 300 μm or | Vb > 300 μm or |
| standard | Vn > 450 μm | Vn > 450 μm |

Vb: Flank wear
Vn: Notch wear

TABLE 4

| | Primary test | Secondary test | |
|---|---|---|---|
| | measured life | measured life | Occurrence of |
| Division | (minute) | (minute) | coating damage |
| Embodiment 1 | 24 | 14 | Not occurred |
| Embodiment 2 | 21 | 11 | Occurred |
| Embodiment 3 | 12 | 8 | Not occurred |
| Embodiment 4 | 8 | 5 | Occurred |
| Embodiment 5 | 17 | 10 | Occurred |
| Embodiment 6 | 16 | 9 | Occurred |
| Embodiment 7 | 18 | 10 | Not occurred |
| Embodiment 8 | 21 | 15 | Not occurred |
| Comparative | 10 | 6 | Not occurred |
| Example 1 | | | |
| Comparative | 15 | 10 | Not occurred |
| Example 2 | | | |

Referring to Table 4, when using the coated cutting tool according to Embodiments, it can be confirmed that heat resistance and wear resistance are improved in high hardness machining. Accordingly, it can be confirmed that the stability of a product is also sufficiently secured as the life of the tool is increased and damage to a workpiece due to tool breakage is reduced.

### Experimental Example 5: Life According to Deposition Time and Whether or not Spontaneous Peeling Occurs

A coated cutting tool was produced by the method according to Embodiment 1, but the total thickness of the cutting layer was adjusted to 4 μm, and deposition was performed such that, as the thickness of a layer to be laminated increased, the number of interlayer laminations in each alternating layer decreased. In order to adjust a thickness between individual layers constituting the cutting layer, the deposition time of each individual layer was adjusted, specifically, by using a ratio of the deposition time of the individual layers.

TABLE 5

| | Thicknesses of individual layers included | | |
|---|---|---|---|
| | in cutting layer (nm) | | |
| Deposition rate | First layer | Second layer | Wear-resistant layer |
| 5.0 | 495 | 312 | 354 |
| 3.0 | 262 | 127 | 139 |
| 2.0 | 153 | 68 | 86 |
| 1.5 | 85 | 54 | 63 |
| 1.0 (standard) | 77 | 34 | 43 |
| 0.5 | 28 | 16 | 23 |

Deposition rate: the deposition rate of 1.0 is the thickness of an individual layer at a basic rotational speed (rpm) of deposition, and is a standard value for the deposition rate. The deposition rates of the remaining individual layers were expressed as relative deposition rates with respect to the deposition rate of 1.0. A relatively increasing deposition rate means that the rotational speed of equipment is slowed and the thicknesses of individual layers become thicker. A relatively decreasing deposition rate means that the rotational speed of equipment is quicken and the thicknesses of individual layers become thinner.

TABLE 6

| | Primary test | Secondary test | Occurrence of |
|---|---|---|---|
| | measured life | measured life | spontaneous |
| Deposition rate | (minute) | (minute) | peeling |
| 5.0 | 12 | 8 | X |
| 3.0 | 20 | 12 | X |
| 2.0 | 24 | 14 | X |
| 1.5 | 16 | 9 | Δ (Partial occurrence) |
| 1.0 (standard) | 11 | 6 | ◯ |
| 0.5 | 8 | 5 | ◯ |

According to an embodiment of the present disclosure, a coated cutting tool having high wear resistance and controlled brittleness may be provided. When using such a coated cutting tool, it is easy to solve a limitation in that, even if the life of a coating has not expired, the coating becomes unusable due to the brittleness of the coating of high hardness.

According to another embodiment of the present disclosure, a coated cutting tool of which the life is extendable by increasing adhesion between layers that constitute a thin film and which secures the stability of a product as damage to a workpiece caused by tool breakage is reduced may be provided.

In addition to the above effects, specific effects of the present disclosure will be described together while explaining specific description for carrying out the present disclosure.

Although preferred embodiments of the present disclosure have been described in detail above, the scope of the present disclosure is not limited thereto, and various modifications and improvements by those skilled in the art using the basic concept of the present disclosure defined in the following claims also fall within the scope of the present disclosure.

What is claimed is:

1. A coated cutting tool comprising:
a substrate; and
a cutting layer disposed on the substrate,
wherein the cutting layer includes a brittleness suppressing layer and a wear-resistant layer disposed on the brittleness suppressing layer,
the substrate includes a hard alloy body such as cemented carbide, cermet, ceramic, cubic boron nitride-based materials, or high-speed steel,
the brittleness suppressing layer includes a first layer and a second layer disposed on the first layer,
the first layer and the second layer each independently includes any one of (Al_{b}Ti_{1-b})X (where 0.6<b<0.8, and X is at least one selected from N, C, CN, NO, CO, and CNO) and (Ti_{c}Al_{1-c})X (where 0.4<c≤0.5, and X is at least one selected from N, C, CN, NO, CO, and CNO), and
the first layer and the second layer include materials different from each other.

2. The coated cutting tool of claim 1, wherein the first layer includes (Ti_{c}Al_{1-c})X (where 0.4<c≤0.5, X is at least one selected from N, C, CN, NO, CO, and CNO) and the second layer includes (Al_{b}Ti_{1-b})X (where 0.6<b<0.8, X is at least one selected from N, C, CN, NO, CO, and CNO).

3. The coated cutting tool of claim 1, wherein the brittleness suppressing layer includes a first alternating layer in which the first and second layers are alternately laminated with each other.

4. The coated cutting tool of claim 3, wherein the first alternating layer includes two or more multilayers, and the thicknesses of the first and second layers constituting the multilayers each independently exceeds 50 nm.

5. The coated cutting tool of claim 4, wherein a thickness ratio of the second layer and the first layer (second layer: first layer) is 1:1.5 to 1:5.

6. The coated cutting tool of claim 1, wherein the wear-resistant layer includes (Ti₁₋ₐSiₐ)X (where 0.1<a<0.3, and X is at least one selected from N, C, CN, NO, CO, and CNO).

7. The coated cutting tool of claim 1, wherein the cutting layer further includes a second alternating layer disposed between the brittleness suppressing layer and the wear-resistant layer.

8. The coated cutting tool of claim 7, wherein the second alternating layer includes at least one structure in which a first wear-resistant layer, the second layer, and the first layer are sequentially laminated, and the first wear-resistant layer includes (Ti₁₋ₐSiₐ)X (where 0.1<a<0.3, and X is at least one selected from N, C, CN, NO, CO, and CNO).

9. The coated cutting tool of claim 7, wherein the cutting layer further includes an intervening layer disposed on the second alternating layer.

10. The coated cutting tool of claim 9, wherein the intervening layer includes a lower layer disposed directly below the wear-resistant layer, and the lower layer includes (Al_{b}Ti_{1-b})X (where 0.6<b<0.8, and X is at least one selected from N, C, CN, NO, CO, and CNO).
